(19) United States
(12) Patent Application Publication
(10) Pub. No.: US 2023/0200083 A1
(43) Pub. Date: Jun. 22, 2023

(54) EMBEDDED MEMORY WITH FERROELECTRIC CAPACITORS & INDEPENDENT TOP PLATE LINES

(71) Applicant: Intel Corporation, Santa Clara, CA (US)

(72) Inventors: Wilfred Gomes, Portland, OR (US); Abhishek Anil Sharma, Portland, OR (US); Uygar Avci, Portland, OR (US)

(73) Assignee: Intel Corporation, Santa Clara, CA (US)

(21) Appl. No.: 17/558,437

(22) Filed: Dec. 21, 2021

(51) Int. Cl. H01L 27/11507; H01L 23/522; H01L 21/768

(52) U.S. Cl. CPC H01L 27/11507; H01L 23/5223; H01L 23/5226; H01L 21/76802; H01L 21/76877

(57) ABSTRACT

Integrated circuits with embedded memory that includes ferroelectric capacitors having first conductor structures coupled to an underlying array of access transistors, and second conductors coupled to independent plate lines that are shunted by a metal strap having a pitch similar to that of the capacitors. The independent plate lines may reduce bit-cell disturbs and/or simplify read/write process while the plate line straps reduce series resistance of the plate lines. The metal straps may be subtractively patterned lines in direct contact with the second capacitor conductors, or may be damascene structures coupled to the second capacitor conductors through vias that also have a pitch similar to that of the capacitors.

### BACKGROUND

Embedded memory is monolithically integrated into host integrated circuitry (i.e., both memory and the host circuitry fabricated on the same die or chip). One embedded memory architecture is DRAM based on a 1T-1C cell that includes a “write,” “select” or “access” transistor and a storage capacitor. An array of such bit-cells may be integrated with host logic circuitry, such as a host microprocessor chip (e.g., a central processing unit or “CPU” core). Integration of both a capacitor memory device and a processor proximate to one another in a same IC chip, for example, enables communication between the memory device and the processor through a chip bus capable of higher bandwidths and/or lower signal latencies relative to packaged IC chips communicating through package interconnects.

A transistor and a capacitor of each 1T-1C cell may be electrically coupled through one or more metal interconnect layers formed in the back-end-of-line (BEOL) over logic circuitry formed in the front-end-of-line (FEOL). The BEOL is the portion of IC fabrication where individual semiconductor devices (whether embedded memory or logic transistors) are interconnected to one another with metal interconnect traces (lines) within a given metallization level and metal vias between multiple metallization levels. These conductive interconnects are embedded in a dielectric material so that the memory device is a monolithic integrated circuit.

In conventional embedded DRAM (eDRAM), each capacitor comprises an insulative dielectric material separating charge stored on capacitor conductors. An embedded memory architecture may rely on the application of a voltage to one capacitor conductor with the other conductor held at some reference (e.g., ground). In a ferroelectric embedded DRAM (FeDRAM), each capacitor comprises a ferroelectric material. An embedded memory architecture may then rely on polarization states of a capacitor's ferroelectric material, which can be changed when an electric field applied across the capacitor conductors is of correct polarity and sufficient strength to alter the semi-permanent dipoles within the ferroelectric material. A given polarization state may be sensed by measuring an amount of charge needed to flip the ferroelectric capacitor to an opposite polarity state. The read cell may then be subsequently rewritten to the previous polarization state to retain the ascertained bit value. An embedded FeDRAM memory architecture therefore needs to apply a voltage to each capacitor conductor relative to the other to sense and rewrite an individual bit-cell.

Accordingly, embedded FeDRAM architectures, and the fabrication techniques associated with those architectures, that reduce bit-cell disturbs and/or simplify the read/write process are commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a schematic of an integrated circuit (IC) with embedded memory including ferroelectric (FE) capacitors and independent plate lines, in accordance with some embodiments;

FIG. 2 is a flow diagram illustrating methods of fabricating the IC illustrated in FIG. 1, in accordance with some embodiments;

FIG. 3A illustrates a first cross-sectional side view of the IC illustrated in FIG. 1, in accordance with some exemplary embodiments with via strapped storage capacitor plate lines;

FIG. 3B illustrates a second, orthogonal, cross-sectional side view of the IC illustrated in FIG. 3A, in accordance with some exemplary embodiments;

FIG. 4A illustrates a cross-sectional side view of the IC illustrated in FIG. 1, in accordance with some alternative embodiments with metal line strapped storage capacitor plate lines;

FIG. 4B illustrates a cross-sectional side view of the IC illustrated in FIG. 4A, in accordance with some embodiments;

FIG. 5 illustrates a mobile computing platform and a data server machine employing an IC with embedded memory including metal strapped storage capacitor plate lines, in accordance with some embodiments; and

FIG. 6 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

The term “adjacent” here generally refers to a position of a thing being next to (e.g., immediately next to or close to with one or more things between them) or adjoining another thing (e.g., abutting it).

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

The term “signal” may refer to at least one current signal, voltage signal, magnetic signal, or data/clock signal.

As used throughout this description, and in the claims, a list of items joined by the term “at least one of or” one or more of can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As used throughout this description, and in the claims, a list of items joined by the term “at least one of or” one or more of can mean any combination of the listed terms.

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

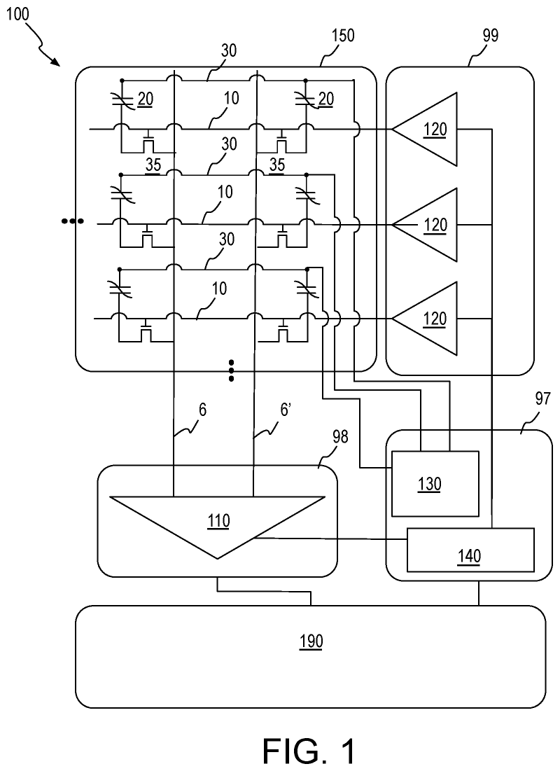

FIG. 1 is a schematic illustrating an IC 100 with embedded memory, in accordance with some embodiments. In this macro-view, a memory array 150 includes a 2D array of storage capacitors 20 networked with conductive traces including multiple bitlines 6 and 6′ (reference), as well as multiple wordlines 10 and multiple independent capacitor plate lines 30. Memory array 150 further includes a select/access transistor 35 electrically coupled to each storage capacitor 20. Memory array 150 is fabricated in the BEOL interconnect levels of IC 100. Hence, all of capacitors 20, bitlines 6, 6′, wordlines 10, select transistors 35 and plate lines 30 are fabricated within, and/or between, various interconnect metallization levels.

Peripheral memory circuitry including at least one of column circuitry 98 and row circuitry 99 may be located at a device level that falls within at least some of the footprint of memory array 150. For example, bitlines 6, 6′ may be electrically coupled to a sense amplifier 110. In further embodiments, wordlines 10 are electrically coupled to wordline drivers 120.

Peripheral memory circuitry further includes control circuitry 97. One or more of column circuitry 98, and/or row circuitry 99, and/or memory array 150 may be electrically coupled to control circuitry 97. Control circuitry 97 may include, for example, various voltage biasing circuits, such as capacitor bias circuitry 130 that includes a charge pump that can be independently coupled to individual ones of a plurality of top capacitor plate lines 30. Hence, in addition to being able to charge up one capacitor plate through application of a voltage to bitlines, plate lines 30 may also charge up the second capacitor plates coupled to a given one of capacitor plate lines 30. Hence, rather than one plate of the storage capacitors being tied together across many wordlines and many bitlines, for example by a continuous sheet of capacitor conductor, the second capacitor conductors are separated into subset populations with each subset of capacitors being associated with either one bitline or with one wordline. In the example illustrated in FIG. 1, plate lines 30 run parallel to wordlines 10 so that a plate of each capacitor 20 coupled to one wordline 10 is tied to one plate line 30. In alternative examples, for example as described further below, plate lines 30 may instead run parallel to bitlines 6 so that a plate of each capacitor 20 coupled to one bitline 6 is tied to one plate line 30. Regardless of the plate line configuration, the subset of capacitors that are electrically coupled by one capacitor plate line 30 are to be coupled to a charge pump independent of the other plate lines. Capacitor bias circuitry 130 may therefore have as many outputs as bitlines or wordlines for a given memory array. Each plate line configuration has some advantages and disadvantages. For example, in the embodiment illustrated in FIG. 1, disturbs are minimized. In the alternative embodiment, disturbs are higher but the read/write process is simplified by biasing the plate voltage.

Control circuitry 97 may also include, for example, various memory management circuitry, such as control logic 140 communicatively coupled into column circuitry 98 and row circuitry 99 so as to permit coordinated operation of sense amplifier 110 and wordline driver 120. Control circuitry 97 may also be fabricated in a device level the falls within the footprint of memory array 150. Control circuitry 97 may, for example, also employ MOSFETs fabricated in a region of a monocrystalline semiconductor device layer (e.g., silicon substrate) that is at least partially underlying memory array 150.

IC 100 further includes host logic circuitry 190. Host logic circuitry 190 is a primary consumer of memory bandwidth supplied by memory array 150. Host logic circuitry 190 may be any application specific IC (ASIC) including one or more IP cores. In some embodiments, host logic circuitry 190 comprises a processor core. In other embodiments, host logic circuitry 190 comprises any of a wireless radio circuit, or floating point gate array (FPGA).

In exemplary embodiments, memory array 150 comprises a 2D array of metal-ferroelectric-metal (MFM) capacitors 20 fabricated over a corresponding array of the access transistors 35. In exemplary embodiments, the individual memory cells/bit-cells include one access transistor 35 and one ferroelectric capacitor 20 (1T-1F). Ferroelectric materials can have much higher values of relative permittivity than dielectric materials. Charge capacitance for a given MFM capacitor area can therefore be much larger for a ferroelectric insulator than for a dielectric insulator. The ferroelectric material may be deposited by chemical vapor deposition, and more specifically atomic layer deposition (ALD), at temperatures compatible with BEOL structures.

FE-capacitors 20 may occupy a footprint over a substrate including logic circuitry including field effect transistors (FETs), for example implementing the peripheral circuitry as described above. CMOS FET circuitry implementing host logic circuitry 190 may be adjacent to the footprint of memory array 150. Access transistors 35 providing wordline and bitline access to the FE-capacitors may reside within the BEOL substantially within the footprint of the FE-capacitor array.

For some exemplary embodiments, access transistor 35 of a 1T-1F storage cell is a thin-film transistor (TFT) rather than a monocrystalline silicon-based transistor (e.g., MOSFET). TFTs are a class of field-effect transistors (FETs) in which the channel material is a deposited thin film rather than a monocrystalline material. The thin film deposition processes employed in TFT fabrication can be relatively low temperature (e.g., below 450° C.), allowing TFTs to be inserted within layers of interconnect metallization of the type that is typically formed only after higher-temperature processing is completed in conventional silicon MOSFET fabrication technology. TFTs can be made using a wide variety of semiconductor materials, such as silicon, germanium, silicon-germanium, as well as various oxide semiconductors (a.k.a. semiconducting oxides) including metal oxides like indium gallium zinc oxide (IGZO), indium zinc oxide (IZO), and the like.

The access transistor 35 of a 1T-1F storage cell may alternatively be a recessed channel array transistor (RCAT). RCATs are a class of field-effect transistors (FETs) in which the gate is recessed into the channel material. Recession into the channel increases the effective channel length of the transistor without increasing the transistor footprint, allowing access transistor 35 to have an area matched to that of an overlying ferroelectric capacitor 20.

As described further below, top capacitor plate series resistance and write disturbs are reduced through the introduction of separate plate lines and a strap of metal having a pitch approximately equal to that of the storage capacitors. Since the separate plate lines may be separately biased by control circuitry, bit-cell disturbs may be reduced. To reduce the electric resistance of each plate line, an electrically shunting strap of metal may be implemented either with an additional damascene BEOL metallization level that includes vias coupling the strap to the storage capacitors of one plate line, or the strap of metal may be implemented with a subtractively patterned metal in direct contact with each top capacitor metal of one plate line.

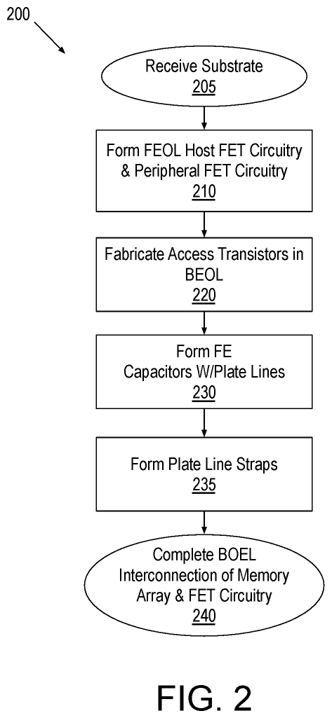

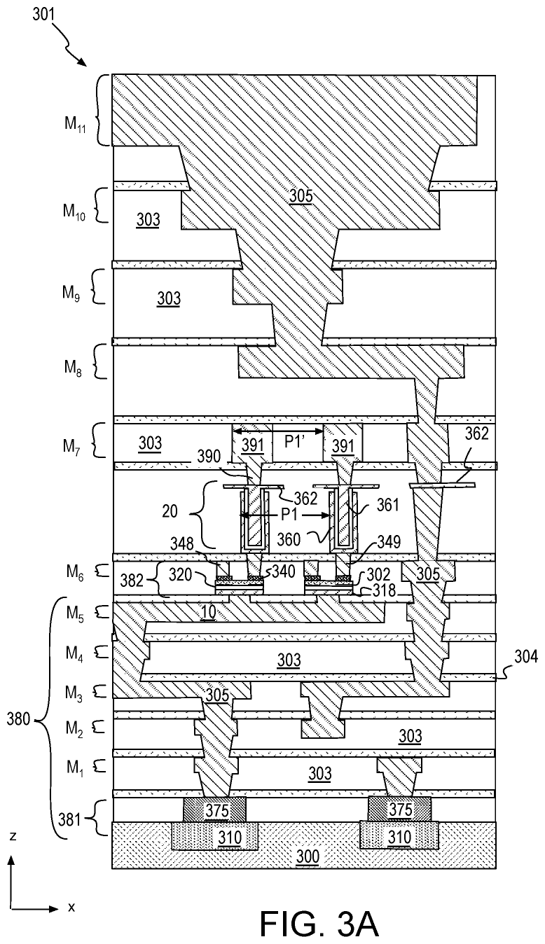

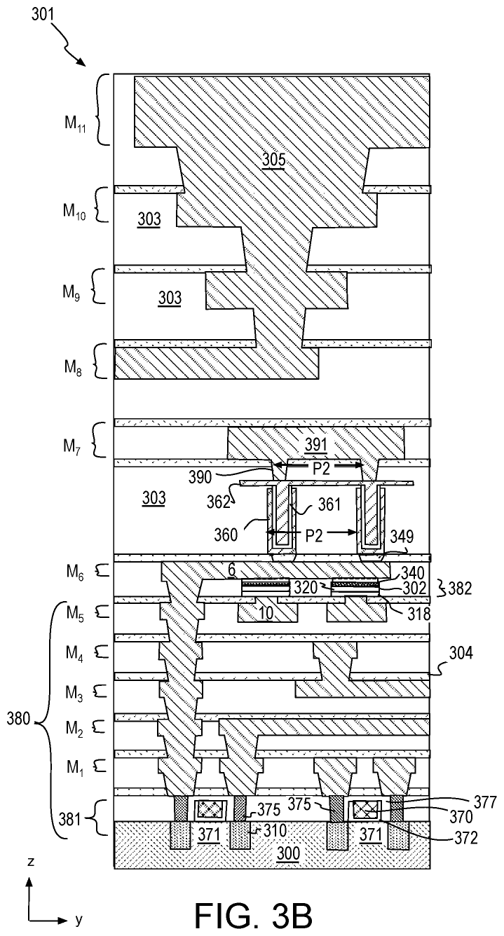

FIG. 2 is a flow diagram illustrating methods 200 for fabricating IC 100 (FIG. 1), in accordance with some embodiments. FIG. 3A and FIG. 3B illustrates two, orthogonal, cross-sectional side views of an IC structure 301 that may be fabricated according to methods 200. IC structure 301 is an exemplary implementation of IC 100 in accordance with some embodiments having capacitor conductors strapped by metal as an electrical shunt reducing resistivity across a plurality of the capacitor conductors that are all to be coupled to a charge pump and sense amplifier. As shown in FIG. 2, methods 200 begin at input 205 where an input substrate is received. FIG. 3A, 3B illustrate an example where the input substrate 300 comprises a monocrystalline semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, substrate 300 is a Group III-N material comprising a Group III majority constituent and nitrogen as a majority constituent (e.g., GaN, InGaN). Other embodiments are also possible, for example where substrate 300 is a Group III-V material comprising a Group III majority constituent and a Group IV majority constituent (e.g., InGaAs, GaAs, GaSb, InGaSb).

Returning to FIG. 2, methods 200 continue at block 210 where FEOL fabrication processes are practiced to form host (e.g., ASIC) logic circuitry and embedded memory peripheral FET circuitry. Any FEOL process(es) may be practiced at block 210. In the example illustrated in FIGS. 3A and 3B, FEOL circuitry 380 includes peripheral logic circuitry of an embedded memory that includes field effect transistors (FETs) 381. CMOS FET circuitry implementing host integrated circuitry (not depicted) may be anywhere laterally adjacent to the peripheral logic circuitry of the embedded memory, but within the same plane as FETs 381.

FETs 381 employ monocrystalline semiconductor material for at least the channel semiconductor 371. FETs 381 further include a gate terminal 370 separated from monocrystalline channel semiconductor by a gate insulator 372. Channel semiconductor separates semiconductor terminals 310. Contact metallization 375 lands on semiconductor terminals 310 and is separated from gate terminal by an intervening insulator 377. FETs 381 may be planar or non-planar devices. In some advantageous embodiments, FETS 381 are finFETs.

FEOL circuitry 380 further includes one or more initial levels of interconnect metallization 305 embedded in dielectric materials 303, 304. In the exemplary embodiment illustrated, FEOL circuitry 380 includes metal-one (M₁), metal-two (M₂) metal-three (M₃), and metal-four (M₄) levels interconnecting FETs 381. In the example, metal-five implements wordline 10.

Returning to FIG. 2, methods 200 continue at block 220 where access transistors are fabricated over the FEOL circuitry, within a BEOL layer. In some embodiments, block 220 comprises fabricating TFTs. The TFTs may be planar channel devices, fin channel devices, or recessed channel devices. In the example illustrated in FIG. 3, a plurality of TFTs 382 is located over FEOL circuitry 380. As shown, all TFTs 382 employ portions of thin film semiconductor layer 302, which is an amorphous or polycrystalline film that may extend across, and/or between, all TFTs 382, or comprise a plurality of physically separated islands. Individual ones of TFTs 382 include a gate terminal (electrode) 318 separated from semiconductor layer 302 by a gate insulator 320. In the exemplary embodiment illustrated, TFTs 382 are “bottom-gate” devices with semiconductor layer 302 deposited over gate terminal 318. Alternatively, top-gate architectures are also possible where at least gate terminal 318 is above semiconductor layer 302. Terminal contact metallization 340 lands on source and drain regions of semiconductor layer 302.

Semiconductor layer 302 may be a group IV semiconductor material, such as silicon (Si), germanium (Ge), and SiGe alloys. However, in some exemplary embodiments, semiconductor layer 302 comprises an oxide semiconductor, or semiconducting oxide, or a semiconductor, comprising a metal and oxygen. Many metal oxide semiconductor materials have a wide band gap oxide channel material offering low leakage. With essentially no minority carriers, majority-minority carrier recombination cannot generate significant off-state leakage current. Through low-leakage, TFTs 382 may enable higher retention rates at higher memory density and enhance the performance of a 1T-1F cell further including a ferroelectric capacitor.

An oxide semiconductor thin film can be amorphous (i.e., having no structural order), or polycrystalline (e.g., having micro-scale to nano-scale crystal grains). Exemplary metal oxides include a transition metal (e.g., IUPAC group 4-10) or post-transition metal (e.g., IUPAC groups 11-15). In advantageous embodiments, the metal oxide includes at least one of Mg, Cu, Zn, Sn, Ti, Ni, Ga, In, Sb, Sr, Cr, Co, V, or Mo. The metal oxides may be suboxides (A₂O), monoxides (AO), binary oxides (AO₂), ternary oxides (ABO₃), and mixtures thereof.

Semiconductor layer 302 may be a p-type, n-type, or intrinsic material. In exemplary embodiments, semiconductor layer 302 is n-type as many oxide semiconductors have been found to be capable of significant electron densities. In some embodiments, semiconductor layer 302 comprises a tin oxide (SnOₓ), such as Tin (IV) oxide, or SnO₂. In other embodiments, the tin oxide is Tin (II) oxide (SnO) or a mixture of SnO and SnO₂, where x may range between 1 and 2. While the range of x may be expanded, semiconducting properties may be lost (e.g., the material becomes a pure conductor if x is to low, and a pure insulator if x is too high). In some other embodiments, semiconductor layer 302 comprises a zinc oxide (ZnOₓ), such as Zn(II) oxide, or ZnO. In other embodiments, the zinc oxide is zinc dioxide (ZnO₂) or a mixture of ZnO and ZnO₂, where x may range between 1 and 2. In some other embodiments, semiconductor layer 302 comprises titanium oxide (TiOₓ), or SnOₓ.

Semiconductor layer 302 or various portions thereof, may be intentionally doped, or not. Compared to intrinsic oxide semiconductor that is not intentionally doped, n-type and p-type oxide semiconductors may have a higher concentration of impurities, such as, but not limited to, one or more group III element, group V element, and/or elemental hydrogen (H), and/or oxygen vacancies. In some embodiments where semiconductor layer 302 comprises ZnOₓ, the dopants may include In and Ga. In some specific examples, semiconductor layer 302 is InGaO₃(ZnO)₅, often referred to simply as IGZO.

Access transistors are coupled to a memory device bitline comprising an interconnect metallization trace within a BEOL metallization level M₆, above TFTs 382. Memory device bitline may alternatively comprise an interconnect metallization within a metallization level M₅, below TFTs 382. As further shown in FIG. 3A and FIG. 3B, metal line 348 provides a bitline connection to contact metallization 340 landing on semiconductor terminals (e.g., drain semiconductor) of access transistors. Source terminals of access transistors are electrically connected to capacitor storage node through interconnect metallization 349. Storage node interconnect metallization 349 is adjacent to, but electrically insulated from, the bitline, and in this example includes a M6 line and an overlying via.

Returning to FIG. 2, methods 200 continue at block 230 where FE capacitors are formed within a BEOL level over the access transistors. At block 230, ferroelectric material is formed on at least one sidewall of a capacitor conductor. As shown in FIG. 3A and FIG. 3B, each storage node interconnect metallization 349 electrically couples a first conductive capacitor plate conductor 360 to a semiconductor terminal (e.g., source semiconductor) of one access transistor. FE capacitors 20 further include another plate conductor 362 that is separated from conductor 360 by an intervening ferroelectric material 361. In the exemplary embodiment shown, conductor 362 is continuous across at least all FE capacitors 20 associated with one bitline 6. In alternative embodiments, capacitor conductor 362 may also be continuous across FE capacitors 20 associated with multiple bitlines, but a single wordline. Although conductors 360 and 362 may have any composition known to be suitable for a storage capacitor, in exemplary embodiments, the compositions are ones that can be deposited by ALD for the sake of high conformality. In some embodiments, conductors 360 and 362 are both of the same metal or metallic compound, with some examples being Ti, TiNₓ.

Ferroelectric material 361 advantageously has a higher relative permittivity than high-K dielectric materials that lack the spontaneous polarization of materials in a ferroelectric phase (orthorhombic, non-centrosymmetric crystallinity). For example, a high-k dielectric comprising predominantly hafnium and oxygen (HfOₓ), but not in a ferroelectric phase, may have a relative permittivity in the range of 10-14. However, hafnium oxide in a ferroelectric phase may have a relative permittivity exceeding 25 (e.g., 30). Although in both instances the HfOₓ comprises predominantly hafnium and oxygen, ferroelectric material 361 is more specifically a ferroelectric phase of the hafnium oxide. Such phases may be achieved, for example, through the addition of a dopant, such as silicon, germanium, aluminum, or yttrium. Although doped ferroelectric HfOₓ is an exemplary embodiment that can be advantageously conformally deposited by ALD, ferroelectric material 361 may also have other compositions similarly amenable to being deposited at temperatures compatible with BEOL structures and with similar thickness conformality.

In exemplary embodiments where capacitor conductor 360 is substantially cylindrical (e.g., a right cylinder that is open at the top), ferroelectric material 361 lines at least an interior sidewall of the cylinder. Capacitor conductor 362 is adjacent to the ferroelectric material 361, likewise lining at least an interior sidewall of the cylinder. Following a deposition of capacitor conductor 362, a subtractive etch process may be utilized to pattern capacitor conductor 362 into separated plate lines running parallel to one of wordline 10 or the bitline 6.

Returning to FIG. 2, methods 200 continue at block 235 where capacitor conductor plate line straps are formed. The plate line straps are to function as an electrical shunt across subset of capacitors that are to be coupled to the same charge pump. Each plate strap may be routed co-linearly with the capacitors of one plate line being shunted by the strap. Therefore, the plate line straps may also be either parallel to the wordline, or parallel to the bitline.

In the example illustrated in FIG. 3A, FE capacitors 20 have a pitch P1 in a first (e.g., z-x) dimension. As further illustrated in FIG. 3B, FE capacitors 20 have a pitch P2 in a second, orthogonal (e.g., z-y) dimension. In some embodiments, pitch P1 is substantially equal to pitch P2, but need not be. As further illustrated in FIG. 3A, co-planar plate line straps 391 of BEOL M₇ are in alignment with capacitors 20 and have a pitch P1′ that is advantageously approximately equal to the pitch P1. In this example, plate line straps 391 run substantially parallel to bitline 6, but may instead run parallel to wordline 10 as depicted in FIG. 1.

As represented by shading, plate line straps 391 have the same composition as the other BEOL interconnect metallization levels, and may be predominantly Cu, for example. To function as electrical shunts, plate line straps 391 are coupled to capacitor conductors 362 by conductive vias 390. Vias 390 may also be predominantly Cu, for example part of a damascene structure further including one of the plate line straps 391. Although not depicted, either or both of vias 390 and plate line straps 391 may include any diffusion barrier known to be suitable, such as, but not limited to Ta and/or TaN.

As shown in FIG. 3B, conductive vias 390 have an orthogonal pitch P2′ running along the length of each plate line strap 391. A smaller pitch P2′ will more greatly reduce the resistance of the capacitor conductors being shunted or strapped by the overlying interconnect metallization. In the illustrated example, pitch P2′ is approximately equal to capacitor pitch P2. Conductive vias 390 may, for example, have substantially the same layout as a capacitor via enlisted to form capacitor conductor 360 so that conductive vias 390 are substantially aligned over each individual ones of capacitors 20.

Returning to FIG. 2, methods 200 end at output 240 where BEOL interconnect of the embedded memory array and/or the underlying FET circuitry is completed. For example, as shown in FIG. 3A and FIG. 3B, metallization levels M8-M11 may be fabricated over the embedded memory array. As shown, adjacent to capacitors 20, M8-M11 may be routed down by M7 features that are co-planar with the vias and plate lines employed within the capacitor array for line-level plate voltage control and sufficiently low plate line resistance.

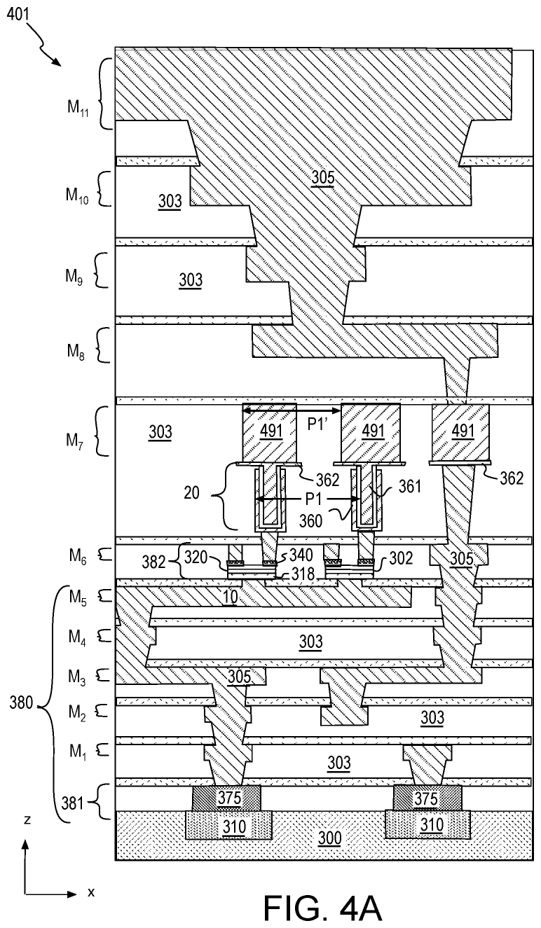

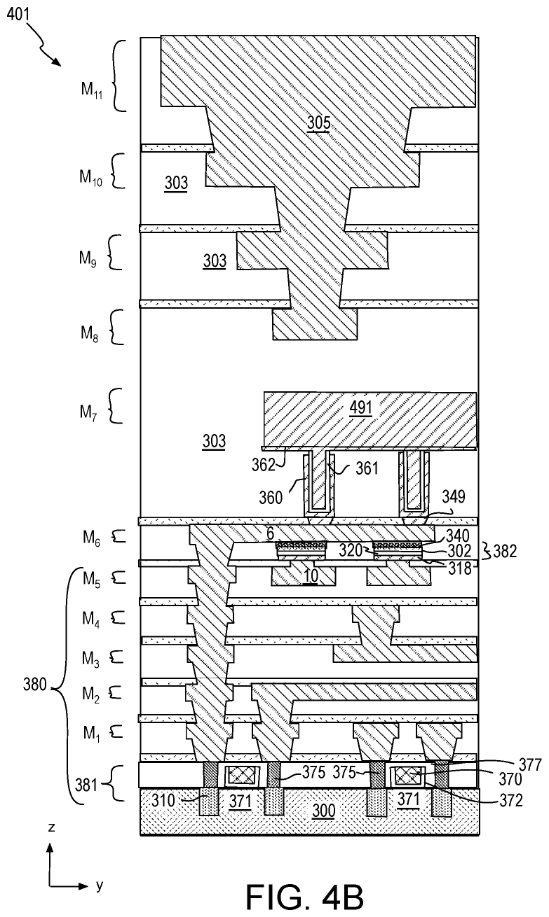

In accordance with some further embodiments, capacitor plate lines may be subtractively patterned and in direct contact with interconnected capacitor conductors. FIGS. 4A and 4B illustrate orthogonal cross-sectional side views of an IC structure 401, which is a portion of the IC 100 illustrated in FIG. 1, in accordance with some exemplary embodiments that include capacitor plate lines. In both FIG. 4A and FIG. 4B, reference numbers from FIG. 3 are retained for structures that may have any of the same properties described for like structures introduced in IC structure 301. As shown in FIG. 4A and FIG. 4B, IC structure 401 shares many of the features of IC structure 301, including FEOL circuitry 380 and ferroelectric capacitors 20. However, instead of a damascene plate line strap, IC structure 401 includes plate line straps 491 that are in direct contact with capacitor conductor 362.

As illustrated in FIG. 4A, co-planar plate line straps 491 are in alignment with FE capacitors 20 and have a pitch P1′ that is advantageously approximately equal to the pitch P1. In this example, plate line straps 491 again run substantially parallel to bitline 6, but may instead run parallel to wordline 10 as depicted in FIG. 1. As represented by shading, plate line straps 491 have a different composition than BEOL interconnect metallization levels (e.g., M6 and M8). In one exemplary embodiment, BEOL metallization level M7 has the same composition as plate line straps 491, so that vertical routing between M8 and M6 is conducted through line 481, as illustrated in FIG. 4A. In alternative embodiments where BEOL metallization level M7 has the same composition as metallization levels M6 and M8 (e.g., predominantly Cu), co-planar plate line straps 491 similarly have a top surface that is co-planar with BEOL metallization level M7.

Plate line straps 491 are advantageously subtractively patterned, for example in substantially as the capacitor conductor 362 is patterned. Plate line straps 491 may therefore comprise any metal that can be subtractively patterned and that provide sufficiently low electrical resistance. For some embodiments, both capacitor conductor 362 and plate line straps 491 have the same composition (e.g., Ti or TiNₓ) A single patterning process may then be practiced to define both capacitor conductor 362 and plate line straps 491. Even where both capacitor conductor 362 and metal line straps 491 have the same composition, deposition processes enlisted each are advantageously different. For some exemplary embodiments, capacitor conductor 362 is deposited by an ALD process of higher conformality and lower deposition rate, while a metal for plate line straps 491 is deposited by a CVD or PVD process of lower conformality at higher deposition rate.

Plate line straps 491 may also have a different composition than capacitor conductors 362. In some embodiments plate line straps 491 are predominantly W, or Ti, or Ru with Ru advantageously having the lowest electrical resistance. If desired, a metal compound further including nitrogen (e.g., WNx, TiNₓ, or RuNₓ) may be deposited and subsequently patterned into plate line straps 491 with any etch process known to be suitable for the composition. For embodiments where plate line straps 491 have a different composition than capacitor conductors 362, either two separate masking operations may be performed to separately define capacitor conductors 362 and plate line straps 491, or a single masking operation may be performed followed by a multi-step etch process that self-aligns capacitor conductors 362 to plate line straps 491. The example shown in FIG. 4A is indicative of separate masking operations as the edge or sidewall of capacitor conductors 360 extend beyond the edge or sidewall of plate line straps 491 (i.e., not self-aligned).

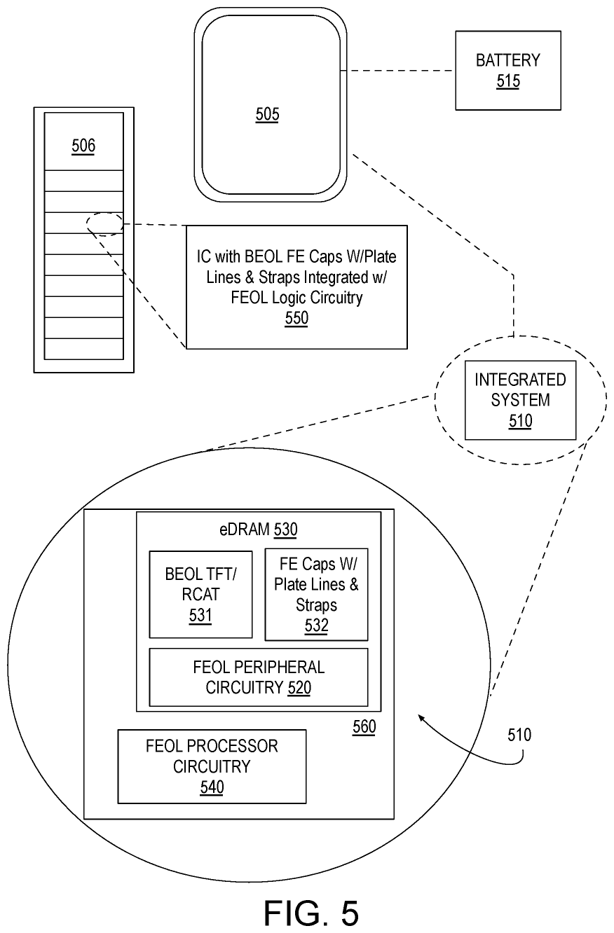

FIG. 5 illustrates a mobile computing platform 505 and a data server machine 506 employing one or more integrated circuits with embedded memory that includes FE capacitors with independent plate lines strapped by a low resistance shunt, for example as described elsewhere herein. Server machine 506 may be any commercial server, for example including any number of high-performance computing platforms disposed within a rack and networked together for electronic data processing, which in the exemplary embodiment includes one or more integrated circuits 550 with embedded memory that includes FE capacitors with independent plate lines strapped by a low resistance shunt, for example as described elsewhere herein. The mobile computing platform 505 may be any portable device configured for each of electronic data display, electronic data processing, wireless electronic data transmission, or the like. For example, the mobile computing platform 505 may be any of a tablet, a smart phone, laptop computer, etc., and may include a display screen (e.g., a capacitive, inductive, resistive, or optical touchscreen), an integrated system 510, and a battery 515.

As illustrated in the expanded view 510, a IC 560 includes FEOL processor circuitry 540 and embedded memory 530. Embedded memory 530 further includes FEOL peripheral circuitry 520, BEOL TFT/RCAT access transistors 531, and FE capacitors 532 coupled to independent plate voltage lines, for example as described elsewhere herein.

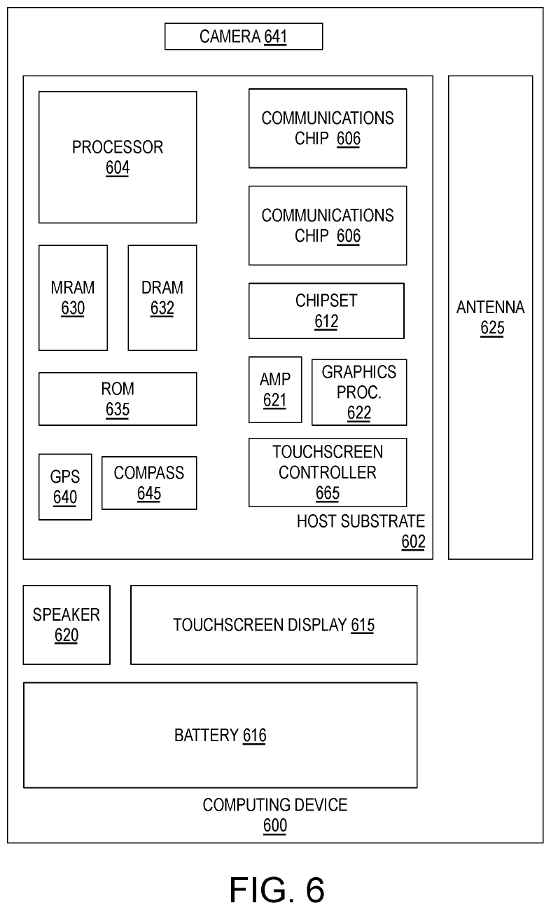

FIG. 6 is a functional block diagram of an electronic computing device 600, in accordance with an embodiment of the present invention. Computing device 600 may be found inside either mobile platform 505 or server machine 506, for example. Device 600 further includes a host substrate 602 hosting a number of components, such as, but not limited to, a processor 604 (e.g., an applications processor). Processor 604 may be physically and/or electrically coupled to host substrate 602. In some examples, processor 604 comprises one or more integrated circuits with embedded memory that includes FE capacitors with independent plate lines strapped by a low resistance shunt, for example as described elsewhere herein. Processor 604 may be implemented with circuitry in any or all of the IC die of the composite IC die package. In general, the term “processor” or “microprocessor” may refer to any device or portion of a device that processes electronic data from registers and/or memory to transform that electronic data into other electronic data that may be further stored in registers and/or memory.

In various examples, one or more communication chips 606 may also be physically and/or electrically coupled to the host substrate 602. In further implementations, communication chips 606 may be part of processor 604. Depending on its applications, computing device 600 may include other components that may or may not be physically and electrically coupled to host substrate 602. These other components include, but are not limited to, volatile memory (e.g., DRAM 632), non-volatile memory (e.g., ROM 635), flash memory (e.g., NAND or NOR), magnetic memory (MRAM 630), a graphics processor 622, a digital signal processor, a crypto processor, a chipset 612, an antenna 625, touchscreen display 615, touchscreen controller 665, battery 616, audio codec, video codec, power amplifier 621, global positioning system (GPS) device 640, compass 645, accelerometer, gyroscope, speaker 620, camera 641, and mass storage device (such as hard disk drive, solid-state drive (SSD), compact disk (CD), digital versatile disk (DVD), and so forth), or the like. In some exemplary embodiments, at least one of the components of device 600 comprises one or more integrated circuits with BEOL FE capacitors and TFT or RCAT access transistors vertically integrated with FEOL logic circuitry, for example as described elsewhere herein.

Communication chips 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 606 may implement any of a number of wireless standards or protocols. As discussed, computing device 600 may include a plurality of communication chips 606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

In first examples, an integrated circuit (IC) die comprises host circuitry comprising first transistors, an embedded memory array structure coupled to the host circuitry. The embedded memory array structure comprises a plurality of capacitors, each of the capacitors comprising a first conductor and a second conductor with a ferroelectric material therebetween. The array structure comprises a plurality of second transistors. A first terminal of each of the second transistors is connected to the first conductor, a second terminal of the second transistors is coupled to one of a plurality of bitlines, and a third terminal of the second transistors is coupled to one of a plurality of wordlines. The array structure comprises a plurality of plate line straps coupled to the second conductor of individual ones of the capacitors that are further coupled to either a same one of the wordlines or a same one of the bitlines.

In second examples, for any of the first examples the IC die comprises one or more first levels of metallization over the first transistors. The memory array structure is over the first levels of metallization, the plurality of second transistors is between the capacitors and the first levels of metallization, and the plurality of plate line straps is within a second level of metallization over the memory array structure. The plate line straps comprise co-planar metal lines having a first pitch approximately equal to a first pitch of the capacitors, and wherein individual ones of the co-planar metal lines are coupled to the second conductor of individual ones of the capacitors that are further coupled to either a same one of the wordlines or a same one of the bitlines.

In third examples, for any of the second examples individual ones of the co-planar metal lines are coupled to the second conductor through a plurality of intervening conductive vias having a second pitch in a direction orthogonal to the first pitch.

In fourth examples, for any of the third examples the second pitch of the vias is approximately equal to a second pitch of the capacitors.

In fifth examples, for any of the third through fourth examples the second conductor and has a first composition, and the co-planar metal lines and plurality of conductive vias have a second composition, different than the first composition.

In sixth examples, for any of the fifth examples the co-planar metal lines and plurality of conductive vias comprise primarily Cu.

In seventh examples, for any of the second through sixth examples individual ones of the co-planar metal lines are in direct contact with the second conductor.

In eighth examples, for any of the second through seventh examples wherein the co-planar metal lines comprise primarily W, or Ti, or Ru, or a nitride thereof.

In ninth examples, for any of the seventh through eighth examples the second conductor comprises primarily Ti or Ti and N.

In tenth examples, for any of the seventh through ninth examples the co-planar metal lines have a top surface co-planar with an adjacent one of the second levels of metallization comprising predominantly copper.

In eleventh examples, for any of the first through tenth examples the ferroelectric material has a relative permittivity over 25.

In twelfth examples, for any of the eleventh examples the ferroelectric material comprises predominantly Hf, O, and one or impurity dopants that comprise at least one of Si or Ge.

In thirteenth examples, for any of the first through twelfth examples a channel material of the second transistors comprises predominantly one or more metals and oxygen.

In fourteenth examples, a system comprises an integrated circuit (IC) die, comprising a plurality of first transistors with monocrystalline channel material, one or more first levels of metallization over the first transistors, NS a memory array structure over the first levels of metallization. The memory array structure comprises a plurality of capacitors, each comprising a first conductor and a second conductor with a ferroelectric material therebetween, a plurality of second transistors between the capacitors and the first levels of metallization, wherein a first terminal of the second transistors is connected to the first conductor. The memory array structure comprises one or more second levels of metallization over the memory array structure, wherein the second levels of metallization comprise co-planar metal lines having a first pitch approximately equal to a first pitch of the capacitors, and individual ones of the co-planar metal lines are coupled to the second conductor. The system comprises a power supply coupled to the IC to power to the IC.

In fifteenth examples, for any of the fourteenth examples the IC die includes at least one of microprocessor core circuitry or floating point gate array (FPGA) circuitry.

In sixteenth examples, a method of fabricating an integrated circuit (IC) die comprises forming a plurality of first transistors comprising monocrystalline channel material, forming one or more first levels of metallization over the first transistors, and forming a memory array structure over the first levels of metallization. Forming the memory array comprises forming a plurality of second transistors, and forming a plurality of first conductor structures over the second transistors, wherein individual ones of the first conductor structures are coupled to a terminal of a corresponding one of the second transistors. Forming the memory array comprises forming ferroelectric material upon a sidewall of the first conductor structures, forming a plurality of second conductors upon a sidewall of the ferroelectric material. Fabricating the IC die comprises forming, over the memory array structure, a plurality of co-planar metal lines having a first pitch approximately equal to a first pitch of the capacitors, and wherein individual ones of the co-planar metal lines are coupled to a plurality of the second conductors.

In seventeenth examples, for any of the sixteenth examples forming the plurality of co-planar metal lines further comprises depositing a metal and subtractively patterning the metal into the co-planar metal lines.

In eighteenth examples, for any of the sixteenth through seventeenth examples depositing the metal comprises depositing predominantly W, Ti, or a nitride thereof.

In nineteenth examples, for any of the sixteenth through eighteenth examples forming the plurality of co-planar metal lines further comprises etching a trench and via openings into a dielectric material over the second conductors, wherein the via openings have a second pitch in a direction orthogonal to the first pitch. Forming the plurality of co-planar metal lines further comprises filling the trench and via openings with predominantly Cu.

In twentieth examples, for any of the sixteenth through nineteenth examples depositing the ferroelectric material comprises atomic layer deposition of a material comprising predominantly hafnium and oxygen.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. An integrated circuit (IC) die, comprising:
host circuitry comprising first transistors; and
an embedded memory array structure coupled to the host circuitry, wherein the embedded memory array structure comprises:
a plurality of capacitors, each of the capacitors comprising a first conductor and a second conductor with a ferroelectric material therebetween;
a plurality of second transistors, wherein a first terminal of each of the second transistors is connected to the first conductor, a second terminal of the second transistors is coupled to one of a plurality of bitlines and a third terminal of the second transistors is coupled to one of a plurality of wordlines; and
a plurality of plate line straps coupled to the second conductor of individual ones of the capacitors that are further coupled to either a same one of the wordlines or a same one of the bitlines.

2. The IC die of claim 1, further comprising one or more first levels of metallization over the first transistors, and wherein:
the memory array structure is over the first levels of metallization;
the plurality of second transistors is between the capacitors and the first levels of metallization; and
the plurality of plate lines straps are within a second level of metallization over the memory array structure, and comprise co-planar metal lines having a first pitch approximately equal to a first pitch of the capacitors, and wherein individual ones of the co-planar metal lines are coupled to the second conductor of individual ones of the capacitors that are further coupled to either a same one of the wordlines or a same one of the bitlines.

3. The IC die of claim 2, wherein individual ones of the co-planar metal lines are coupled to the second conductor through a plurality of intervening conductive vias having a second pitch in a direction orthogonal to the first pitch.

4. The IC die of claim 3, wherein the second pitch of the vias is approximately equal to a second pitch of the capacitors.

5. The IC die of claim 3, wherein the second conductor and has a first composition, and the co-planar metal lines and plurality of conductive vias have a second composition, different than the first composition.

6. The IC die of claim 5, wherein the co-planar metal lines and plurality of conductive vias comprise primarily Cu.

7. The IC die of claim 2, wherein individual ones of the co-planar metal lines are in direct contact with the second conductor.

8. The IC die of claim 7, wherein the co-planar metal lines comprise primarily W, or Ti, or Ru, or a nitride thereof.

9. The IC die of claim 7, wherein the second conductor comprises primarily Ti or Ti and N.

10. The IC die of claim 7, wherein the co-planar metal lines have a top surface co-planar with an adjacent one of the second levels of metallization comprising predominantly copper.

11. The IC die of claim 1, wherein the ferroelectric material has a relative permittivity over 25.

12. The IC die of claim 11, wherein the ferroelectric material comprises predominantly Hf, O, and one or impurity dopants that comprise at least one of Si or Ge.

13. The IC die of claim 1, wherein a channel material of the second transistors comprises predominantly one or more metals and oxygen.

14. A system comprising:
an integrated circuit (IC) die, comprising:
a plurality of first transistors with monocrystalline channel material;
one or more first levels of metallization over the first transistors;
a memory array structure over the first levels of metallization, wherein the memory array structure comprises:
a plurality of capacitors, each comprising a first conductor and a second conductor with a ferroelectric material therebetween;
a plurality of second transistors between the capacitors and the first levels of metallization, wherein a first terminal of the second transistors is connected to the first conductor; and
one or more second levels of metallization over the memory array structure, wherein the second levels of metallization comprise co-planar metal lines having a first pitch approximately equal to a first pitch of the capacitors, and wherein individual ones of the co-planar metal lines are coupled to the second conductor; and
a power supply coupled to the IC to power to the IC.

15. The system of claim 14, wherein:
the IC die includes at least one of microprocessor core circuitry or floating point gate array (FPGA) circuitry.

16. A method of fabricating an integrated circuit (IC) die, the method comprising:
forming a plurality of first transistors comprising monocrystalline channel material;
forming one or more first levels of metallization over the first transistors;
forming a memory array structure over the first levels of metallization, wherein the forming the memory array structure comprises:
forming a plurality of second transistors;
forming a plurality of first conductor structures over the second transistors, wherein individual ones of the first conductor structures are coupled to a terminal of a corresponding one of the second transistors;
forming ferroelectric material upon a sidewall of the first conductor structures;
forming a plurality of second conductors upon a sidewall of the ferroelectric material; and
forming, over the memory array structure, a plurality of co-planar metal lines having a first pitch approximately equal to a first pitch of the capacitors, and wherein individual ones of the co-planar metal lines are coupled to a plurality of the second conductors.

17. The method of claim 16, wherein forming the plurality of co-planar metal lines further comprises depositing a metal and subtractively patterning the metal into the co-planar metal lines.

18. The method of claim 17, wherein depositing the metal comprises depositing predominantly W, Ti, or a nitride thereof.

19. The method of claim 16, wherein forming the plurality of co-planar metal lines further comprises:
etching a trench and via openings into a dielectric material over the second conductors, wherein the via openings have a second pitch in a direction orthogonal to the first pitch;
filling the trench and via openings with predominantly Cu.

20. The method of claim 16, wherein depositing the ferroelectric material comprises atomic layer deposition of a material comprising predominantly hafnium and oxygen.
